(19) United States
(12) Patent Application Publication
(10) Pub. No.: US 2010/0157547 A1
(43) Pub. Date: Jun. 24, 2010

(54) ELECTRONIC DEVICE MODULE

(75) Inventors: EN LIANG SHEN, Yunlin County (TW); MENG HSIA HU, Taichung City (TW)

Correspondence Address: WPAT, PC;INTELLECTUAL PROPERTY ATTORNEYS, 2030 MAIN STREET, SUITE 1300, IRVINE, CA, 92614, US

(73) Assignee: STARCHIPS TECHNOLOGY INC., HSIN-CHU (TW)

(21) Appl. No.: 12/578,719

(22) Filed: Oct. 14, 2009

(30) Foreign Application Priority Data
Dec. 23, 2008 (TW) 097150179

(51) Int. Cl. H05K 7/00

(52) U.S. Cl. 361/748

(57) ABSTRACT

An electronic device module comprises a carrier and first and second device regions. The first device region comprises a plurality of serially-connected devices deposited on the carrier, and the second device region is adjacent to the first device region and comprises a plurality of serially-connected devices. The voltage potential of the plurality of the serially-connected devices in the first device region is substantially the same as that of the plurality of the serially-connected devices in the second device region whereby damage due to short circuit of the adjacent plurality of serially-connected devices is avoided.

### BACKGROUND OF THE INVENTION

1. Field of the Invention

The present invention relates to an electronic device module, and more particularly to an electronic device module with short circuit protection.

2. Description of the Related Art

With the development of the semiconductor manufacturing technology, the scale of electronic devices is continuously being reduced. Therefore, traditional connecting methods, such as the pin-through-hole (THT) method for connecting electronic devices to electronic carriers, i.e., printed circuit boards (PCB), circuit boards, or substrates, cannot handle the highly integrated current circuit design. Depositing a THT device on an electronic carrier requires drilling a hole in the carrier and applying tin solder to fix the THT device on the bottom side of the carrier; therefore the devices of this type occupy space on both sides of the electronic carrier and require a larger welding spot at the connection. In addition, THT devices usually have larger volume and occupy more space on the electronic carrier, and so surface mounting technique (SMT) has largely replaced the THT technique in current assembly processes to meet the requirement of miniaturized structures of the market.

In the case of using SMT devices, because their pins and the main body are soldered on the same side of the electronic carrier, additional drilled holes are not required. Meanwhile, the SMT technique can be utilized to connect electronic devices on both sides of the electronic carrier, and thus improves the usage rate of the space significantly. In addition, due to their smaller volume and more competitive price, the SMT devices have already become common in the market.

FIG. 1A shows a top view of a conventional electronic device module 10. Referring to FIG. 1A, the electronic device module 10 comprises a substrate 11 and two device regions 12 and 13. Each device region 12 and 13 is configured to contain a group of serially-connected devices. FIG. 1A shows an example of the device region 12 comprising a plurality of pairs of solder pads 141, 142, 151, 152, 161, and 162 deposited on the surface of the substrate 11. Both terminals of an electronic device 14 are connected to the corresponding solder pads 141 and 142 via a solder paste. Subsequently, the terminals of the electronic device 14 are electrically connected to other circuit layers or signals of the substrate by a via adjacent to the solder pad or by a wire (not shown).

FIG. 1B shows a circuit diagram of the conventional electronic device module 10 according to one embodiment of the present invention. As shown in FIG. 1B, the group of the serially-connected devices in the device region 12 comprises devices 14, 15, and 16, and the group of the serially-connected devices in the device region 13 comprises devices 17, 18, and 19. The groups of the serially-connected devices are respectively connected between a power source V_{DD} and ground. Referring to FIG. 1B, the terminal 141 of the device 14 is electrically connected to the power source V_{DD}, the terminal 162 of the device 16 is electrically connected to ground, the terminal 171 of the device 17 is electrically connected to the power source V_{DD}, and the terminal 192 of the device 19 is electrically connected to ground.

Due to the highly integrated characteristic of the devices, when the tin solder of the solder pad of the device exceeds a slight tolerance or has a solder extrusion phenomenon produced by diffusion, a short circuit will occur between the tin solders. Referring to FIG. 1A, because the terminal 162 of the device 16 is electrically connected to ground and the terminal 171 of the device 17 is electrically connected to the power source V_{DD}, and the terminals 162 and 171 are deposited at the boundary between the device regions 12 and 13, when the tin solders at the boundary are short, the power source V_{DD} is connected to ground which produces a greatly increased short current. Such large short current may damage electronic products utilizing the electronic device module. On the basis of the above, there is a need to provide an electronic device module so as to improve the reliability and the production yield of the electronic products.

### SUMMARY OF THE INVENTION

An aspect of the present invention is to reduce damage to adjacent serially-connected devices due to a short circuit.

According to one embodiment of the present invention, an electronic device module comprises a carrier and first and second device regions. The first device region comprises a plurality of serially-connected devices deposited on the carrier, and the second device region is adjacent to the first device region and comprises a plurality of serially-connected devices. The voltage potential of the plurality of the serially-connected devices in the first device region is substantially the same as that of the plurality of the serially-connected devices in the second device region whereby damage due to short circuit of the adjacent plurality of serially-connected devices is avoided.

### BRIEF DESCRIPTION OF THE DRAWINGS

The invention will be described according to the appended drawings in which:

FIG. 1A shows a top view of a conventional electronic module;

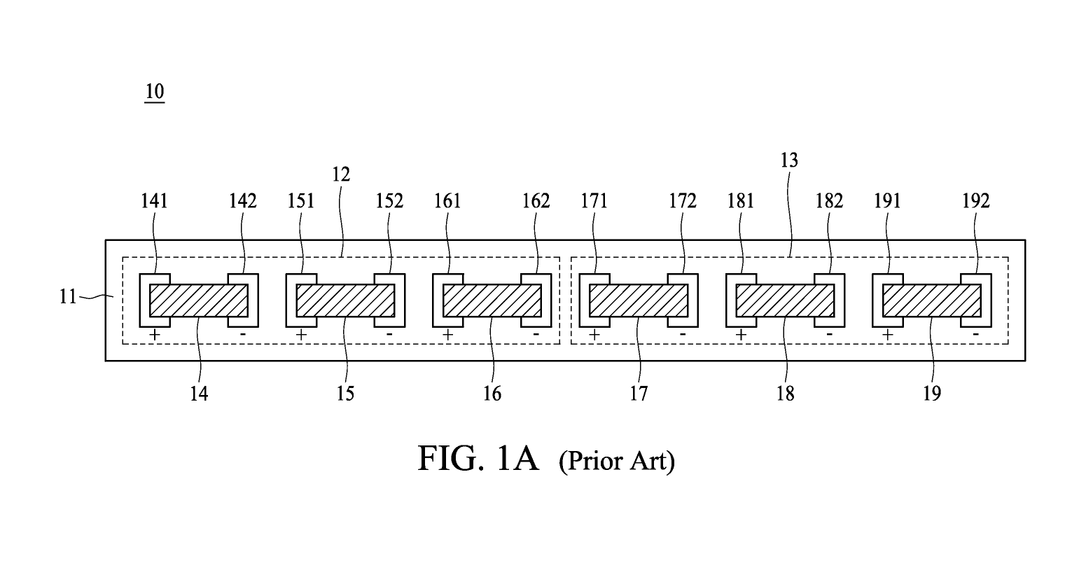

FIG. 1B shows a circuit diagram of the conventional electronic module according to one embodiment of the present invention;

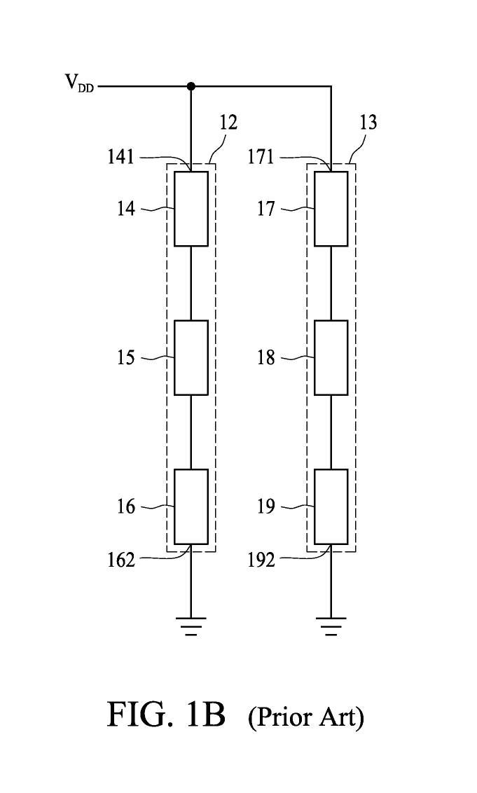

FIG. 2A shows a top view of an electronic module according to one embodiment of the present invention;

FIG. 2B shows a circuit diagram of the electronic module according to one embodiment of the present invention; and

FIG. 2C shows a light emitting module utilizing the aforementioned arrangement of the electronic devices.

### DETAILED DESCRIPTION OF THE INVENTION

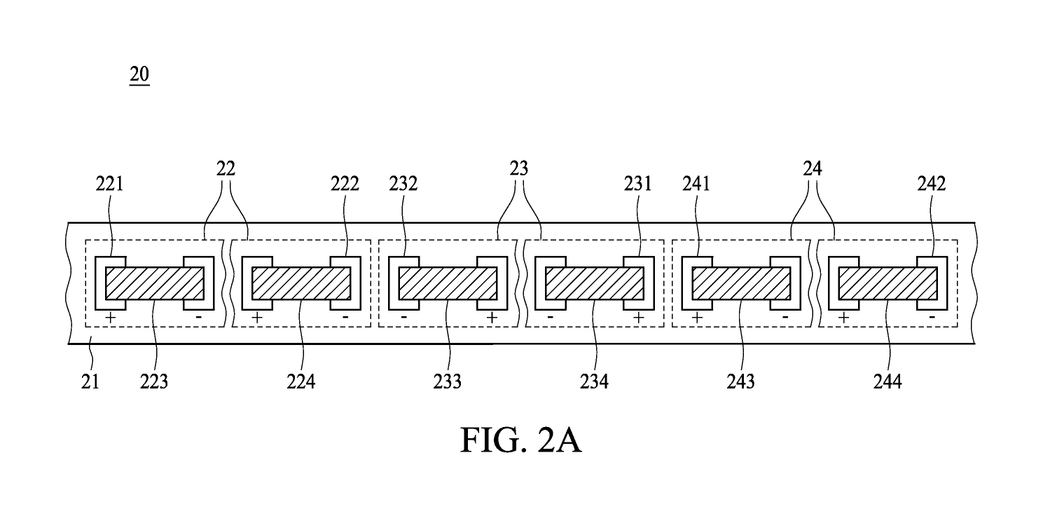

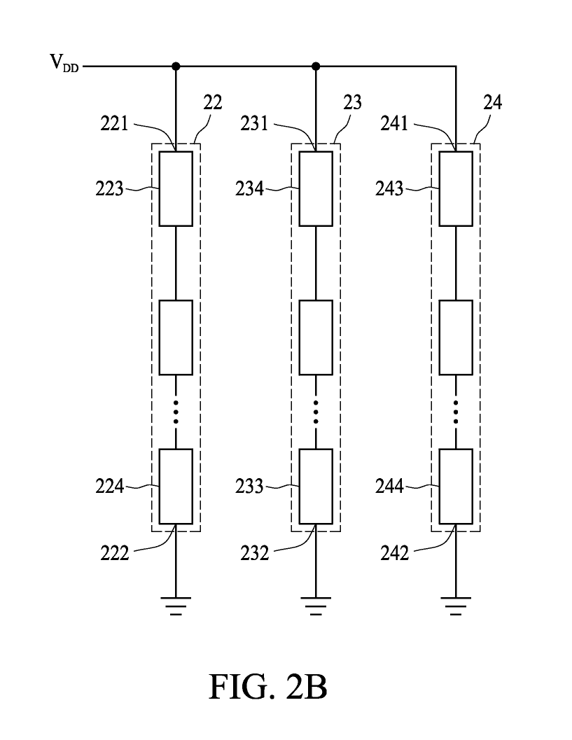

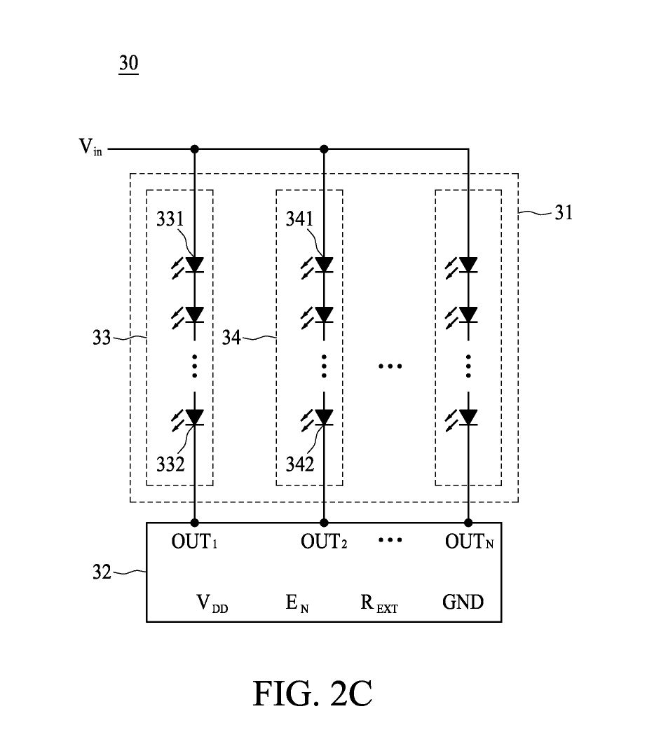

FIG. 2A shows a top view of an electronic device module 20 according to one embodiment of the present invention. Referring to FIG. 2A, the electronic device module 20 comprises a carrier 21 and a plurality of device regions 22, 23, and 24, and the device regions 22, 23, and 24 are deposited on the surface of the substrate 21. Each of the device regions 22, 23, and 24 has first and second terminals deposited respectively on the solder pad on the surface of the substrate 21. The device regions 22, 23, and 24 are configured to contain a group of serially-connected devices.

FIG. 2B shows a circuit diagram of the electronic device module 20 according to one embodiment of the present invention, wherein the group of the serially-connected devices in the device region 22 comprises devices 223 and 224, the group of the serially-connected devices in the device region 23 comprises devices 233 and 234, and the group of the serially-connected devices in the device region 24 comprises devices 243 and 244. Each of the groups of the serially-connected devices 22, 23, and 24 is respectively connected between a power source V_{DD} and ground. One terminal of the device 223 in the device region 22 is connected to the first terminal 221 of the device region 22, that is, the power source, and one terminal of the device 224 is connected to the second terminal 222 of the device region 22, that is, the ground. One terminal of the device 233 in the device region 23 is connected to the second terminal 232 of the device region 23, that is, the ground, and one terminal of the device 234 is connected to the first terminal 231 of the device region 23, that is, the power source. Also, one terminal of the device 243 in the device region 24 is connected to the first terminal 241 of the device region 24, that is, the power source, and one terminal of the device 244 is connected to the second terminal 242 of the device region 24, that is, the ground.

Referring to FIG. 2A, in this embodiment, the first terminal 221 is deposited in the device region 22 according to a direction of a first side of the substrate 21, and the second terminal 222 is deposited in the device region 22 according to a direction of a second side of the substrate 21. The second terminal 232 is deposited in the device region 23 according to the direction of the first side of the substrate 21, and the first terminal 231 is deposited in the device region 23 according to the direction of the second side of the substrate 21. Because the second terminal 222 is electrically connected to the ground, and the second terminal 232 is also electrically connected to the ground, such arrangement can prevent failure when a short circuit occurs between the second terminal 222 and the second terminal 232.

In addition, in this embodiment, the first terminal 241 is deposited in the device region 24 according to the direction of the first side of the substrate 21, and the second terminal 242 is deposited in the device region 24 according to the direction of the second side of the substrate 21. That is, each of the plurality of the serially-connected devices in the device regions 22, 23, and 24 has the same voltage polarity arrangement, i.e., (+, −, +, −, . . . +, −). The direction of the voltage polarity arrangement of the serially-connected devices 223 and 224 in the device region 22 is opposite to that of the serially-connected devices 233 and 234 in the device region 23, and the direction of the voltage polarity arrangement of the serially-connected devices 243 and 244 in the device region 24 is the same as that of the serially-connected devices 223 and 224 in the device region 22. Because the first terminal 231 in the device region 23 is electrically connected to the power source, and the first terminal 241 in the device region 24 is also electrically connected to the power source, such arrangement can prevent failure when a short circuit occurs between the first terminal 231 and the first terminal 241. In addition, after the serially-connected devices are deposited in the device regions 22, 23, and 24, an encapsulating material is applied to cover the serially-connected devices to protect the devices from pollution, humidity and other environmental impurities.

According to one embodiment of the present invention, the serially-connected devices comprise passive devices, such as a resistor, an inductor, or a capacitor. In another embodiment, the serially-connected devices can comprise a plurality of light emitting diodes (LEDs). FIG. 2C shows a light emitting module 30 utilizing the aforementioned arrangement of the electronic devices. The light emitting module 30 comprises a light emitting unit 31 and a driving device 32, both deposited on a carrier (not shown). Light emitting rows 33 and 34 are composed of a plurality of LEDs connected in series, and the light emitting unit 31 is composed of a plurality of light emitting rows connected in parallel. Each light emitting row 33 and 34 is connected to a constant voltage Vᵢₙ and light emitting signals of the light emitting rows 33 and 34 are controlled by the driving device 32. The driving device comprises a plurality of output terminals OUT₁-OUT_{N} connected to the light emitting rows, a voltage source terminal V_{DD}, a ground terminal GND, a control terminal Rₑₓₜ, and an enable terminal EN.

Referring to FIG. 2C, a first terminal 331 of the light emitting row 33 is connected to the constant voltage Vᵢₙ and a second terminal 332 is connected to the output terminal OUT₁. In similar arrangement, a first terminal 341 of the light emitting row 34 is connected to the constant voltage Vᵢₙ and a second terminal 342 is connected to the output terminal OUT₂. The arrangement of the light emitting rows 33 and 34 according to one embodiment of the present invention is illustrated below. The first terminal 331 of the light emitting row 33 and the second terminal 342 of the light emitting row 34 are deposited according to the direction of the first side of the carrier, and the second terminal 332 of the light emitting row 33 and the first terminal 341 of the light emitting row 34 are deposited according to the direction of the second side of the carrier. In this arrangement, because the voltage potentials of the output terminal OUT₁ and OUT₂ are substantially the same, the light emitting module 30 will not fail when the second terminal 332 of the light emitting row 33 shorts to the second terminal 342 of the light emitting row 34.

The arrangement of the light emitting rows 33 and 34 according to another embodiment of the present invention is illustrated below. The second terminal 332 of the light emitting row 33 and the first terminal 341 of the light emitting row 34 are deposited according to the direction of the first side of the carrier, and the first terminal 331 of the light emitting row 33 and the second terminal 342 of the light emitting row 34 are deposited according to the direction of the second side of the carrier. In this arrangement, because the voltage potentials of the first terminal 331 of the light emitting row 33 and the first terminal 341 of the light emitting row 34 are the same, the light emitting module 30 will not fail when the first terminal 331 shorts to the first terminal 341.

The term “electrically connected” in the content refers to a method in which solder pads are connected by a via through different layers of a carrier, or solder pads are connected by a wire on the same side of the carrier. The term “deposited” as used above refers to a method in which the electronic devices and the carrier are connected by surface mount, flip-chip, bump, or wire bonding.

The above-described embodiments of the present invention are intended to be illustrative only. Numerous alternative embodiments may be devised by those skilled in the art without departing from the scope of the following claims.

What is claimed is:

1. An electronic device module, comprising:
a carrier;
a first device region comprising a plurality of serially-connected devices disposed on the carrier; and
a second device region being adjacent to the first device region, the second device region comprising a plurality of serially-connected devices;
wherein the voltage potential of the plurality of the serially-connected devices in the first device region is substantially the same as that of the plurality of the serially-connected devices in the second device region, whereby damage due to short circuit of the adjacent plurality of serially-connected devices is avoided.

2. The electronic device module of claim 1, wherein an electrical connection of the plurality of the serially-connected devices passes through a side edge thereof.

3. The electronic device module of claim 1, wherein each of the plurality of the serially-connected devices in the first and second device regions has the same voltage polarity arrangement, and the direction of the voltage polarity arrangement of the serially-connected devices in the second device region is opposite to that of the serially-connected devices in the first device region.

4. The electronic device module of claim 1, further comprising a third device region being adjacent to the second device region, the third device region comprising a plurality of serially-connected devices, wherein the voltage potential of the plurality of serially-connected devices in the second device region is substantially the same as that of the plurality of serially-connected devices in the third device region, whereby damage due to short circuit of the adjacent plurality of serially-connected devices is avoided.

5. The electronic device module of claim 4, wherein an electrical connection of the plurality of serially-connected devices is through a side edge thereof.

6. The electronic device module of claim 4, wherein each of the plurality of the serially-connected devices in the first, second, and third device regions has the same voltage polarity arrangement, the direction of the voltage polarity arrangement of the serially-connected devices in the second device region is opposite to that of the serially-connected devices in the first device region, and the direction of the voltage polarity arrangement of the serially-connected devices in the third device region is the same as that of the serially-connected devices in the first device region.

7. The electronic device module of claim 3, wherein the voltage polarity arrangement is according to the combination of a power source and a reference voltage, or the combination of an input reference voltage and an output reference voltage.

8. The electronic device module of claim 6, wherein the voltage polarity arrangement is according to the combination of the power source and the reference voltage, or the combination of the input reference voltage and the output reference voltage.

9. The electronic device module of claim 1, further comprising an encapsulating material covered above the serially-connected devices in the first and second device regions.

10. The electronic device module of claim 1, wherein the serially-connected devices are light emitting diodes.

11. The electronic device module of claim 1, wherein the serially-connected devices are passive devices.

12. The electronic device module of claim 1, wherein the carrier is one of a package substrate for chip package, a circuit board, and a printed circuit board.
